(19) United States
(12) Patent Application Publication
(10) Pub. No.: US 2002/0180057 A1
(43) Pub. Date: Dec. 5, 2002

(54) Chip stack-type semiconductor package

(76) Inventors: I-Tseng Lee, Chiao-Tou Hsiang (TW); Chih-Ming Chung, Ta-She Hsiang (TW)

Correspondence Address: J.C Patents, Inc., 1340 Reynolds Ave., Suite 114, Irvine, CA, 92614, US

(21) Appl. No.: 09/927,657

(22) Filed: Aug. 10, 2001

(30) Foreign Application Priority Data
May 31, 2001 (TW) 90113162

(51) Int. Cl. H01L 23/52

(52) U.S. Cl. 257/777

(57) ABSTRACT

A chip stack-type semiconductor package comprises: a substrate having a through hole penetrating there through, the substrate further having a plurality of first mounting pads and a plurality of second mounting pads; a first chip having a plurality of first bonding pads; a second chip having a plurality of second bonding pads, a backside surface of the second chip adhered onto a backside surface of the first chip, a active surface of the second chip adhered onto the substrate, the second bonding pads exposed to the inside of the through hole of the substrate; a plurality of first wires, connecting the first bonding pads and the first mounting pads; a plurality of second wires, connecting the second bonding pads and the second mounting pads; and a molding compound enveloping the first chip, the second chip, the first wires and the second wires.

### CROSS-REFERENCE TO RELATED APPLICATION

This application claims the priority benefit of Taiwan application serial no. 90113162, filed May 31, 2001.

### BACKGROUND OF THE INVENTION

1. Field of the Invention

The invention relates in general to a chip stack-type semiconductor package. More particularly, the invention relates to a semiconductor package for a plurality of stack chips with bonding wires on both corresponding surfaces of a substrate.

2. Description of the Related Art

Recently, following the change of electronics technology with each passing day, high-tech electronic products with relative comfort and multi-function have been presented to the public one after another. The design fashion of various electronic products tends generally towards lightness, thinness, shortness and smallness. Therefore, as far as the field of semiconductor packages is concerned, a lot of package structures are devised in accordance with the concept of the multi-chip package in order to reduce the volume of semiconductor packages and enhance electronic efficiency thereof.

FIG. 1 is a schematic cross-sectional view showing a conventional semiconductor package. A semiconductor package 100 is provided with a chip 110, a substrate 140, a molding compound 150, a plurality of wires 160 and a plurality of solder balls 170. The chip 110 has an active surface 112, on the central region of which a plurality of bonding pads 114 are provided. The substrate 140 has a first surface 142 and a corresponding second surface 144, and a plurality of mounting pads 146 and a plurality of ball pads are formed on the second surface 144 of the substrate 140. A through hole 180 is provided on the central region of the substrate 140 and the mounting pads 146 surround the border region of the through hole 180. The edge region of the active surface 112 of the chip 110 is adhered onto the first surface 142 of the substrate 140. The bonding pads 114 are electrically connected to the mounting pads 146 by the wires 160. The molding compound 150 is filled inside of the through hole 180 to cover the wires 160, the bonding pads 114 and the mounting pads 146. The solder balls 170 are attached on the ball pads 148 of the substrate 140.

As far as the spatial employment of a semiconductor package is concerned, as only one chip 110 is packed in the above-mentioned semiconductor package 100, the volume of whole circuits is relatively large while the density of the semiconductor package 100 is relatively low. In addition, the circuits of the substrates 140 are formed adjacent to the second surface 144 thereof, while there are almost no circuits in the part close to the first surface 142 of the substrate 140. Such a circuit structure of the substrate 140 is not efficiently arranged in the internal space thereof.

As described above, in order to enhance the spatial employment in a semiconductor package, a chip stack-type semiconductor package is provided to supplement the shortcoming, as shown in FIG. 2, a schematic cross-sectional view drawing a conventional chip stack-type semiconductor package. A semiconductor package 200 is provided with a first chip 220, a second chip 230, a substrate 240, a plurality of wires 260a, 260b, a plurality of solder balls 270 and a molding compound 250. The first chip 220 and the second chip 230 have active surfaces 222, 232 and corresponding backchip surfaces 224, 234 respectively. A plurality of bonding pads 226, 236 are formed on the border region of the active surfaces 222, 232 of the first chip 220 and the second chip 230 respectively. The backchip surface 224 of the first chips 220 is adhered onto the central region of the active surface of the second chip 230 and the measure of the horizontal cross-sectional area of the first chip 220 must be smaller than that of the second chip 230. The substrate 240 has a first surface 242 and a corresponding second surface 244, wherein a chip pad 246 and a plurality of mounting pads 248a, 248b surrounding the chip pad 246 are formed on the first surface 242 and a plurality of ball pads 249 are formed on the second surface 244. The backchip surface 234 of the second chips 230 is adhered onto the chip pad 246. The bonding pads 226 of the first chip 220 are electrically connected with the mounting pads 248a of the substrate 240 by the wires 260a; the bonding pads 236 of the second chip 230 are electrically connected with the mounting pads 248b of the substrate 240 by the wires 260b. The molding compound 250 covers the first chip 220, the second chip 230, wires 260a, 260b and the first surface 242 of the substrate 240. The solder balls 270 are attached on the ball pads 249 formed on the second surface 244 of the substrate 240.

The above-mentioned semiconductor package 200 is limited to the condition that the measure of the horizontal cross-sectional area of the first chip 220 must be smaller than that of the second chip 230. Once the measure of the horizontal cross-sectional area of the first chip 220 is close to that of the second chip 230, it is impossible to package according to the structure of the semiconductor package 200. Moreover, as far as the mounting pads 248a connected to the first chip 220 by wires 260a and the mounting pads 248b connected to the second chips 230 by wires 260b are concerned, the circuits are excessively concentrated and the pitch there between is relatively small such that the kind of the substrate 240 is not easily designed and of high cost. In addition, the wires 260a of the semiconductor package 200 must be long enough to cross the position of the wires 260b, or the wires 260a, 260b may touch each other, and so the first chip 220 and the second chip 230 can be invalid. Furthermore, since the wires 260a are relatively long, the delay and decay of a signal may occur, the effect of the first chip 220 and the second chip 230 may be reduced, and the wires 260a may collapse while encapsulating.

As far as the above-mentioned chip stack-type semiconductor package, the measure of the horizontal cross-sectional area of the first chip must be smaller than that of the second chip such that it is in practice limited. A chip stack-type semiconductor package is provided to supplement the shortcoming, as shown in FIG. 3, a schematic cross-sectional view drawing a conventional chip stack-type semiconductor package. The semiconductor package 300 further includes a spacer 390 positioned between the first chip 320 and the second chip 330, whereby the measure of the horizontal cross-sectional area of the first chip 320 can be larger than that of the second chip 330. The thickness of the spacer 390 must be enough to make the wires 390 not contact the first chip 320. However, because the spacer 390, between the first chip 320 and the second chip 330, occupies a space, the volume of the semiconductor package 300 is increased and the requirement of lightness, thinness, shortness and smallness is not achieved. Meanwhile, the wires 360 are even longer in such a way that the opportunity of generating the delay and decay of a signal rises and the wires 260a are more easily collapsed while encapsulating.

### SUMMARY OF THE INVENTION

It is an objective according to the present invention to provide a chip stack-type semiconductor package shortening the length of wires, enhancing the electrical efficiency and, meanwhile, dropping the risk of collapsing wires.

It is another objective according to the present invention to provide a chip stack-type semiconductor package improving the disposition of the circuits in a substrate.

It is another objective according to the present invention to provide a chip stack-type semiconductor package with a plurality of chips stacked therein and thus it is beneficial to integrated circuit systems. As far as a cost is concerned, the cost of a semiconductor package packing a plurality of chips, according to the present invention, is lower than that of a plurality of semiconductor packages packing the chips respectively.

It is the other objective according to the present invention to provide a chip stack-type semiconductor package that is not limited to the approximation of the dimensions of the chips.

To achieve the foregoing and other objects and in accordance with the purpose of the present invention, the present invention provides a chip stack-type semiconductor package comprising: a substrate having a first surface and a corresponding second surface, the substrate further having a through hole penetrating there through, the substrate further having a plurality of first mounting pads and a plurality of second mounting pads, the first mounting pads formed on the first surface of the substrate, the second mounting pads formed on the second surface of the substrate; a first chip having a first active surface and a corresponding first backside surface and furthermore the first chip having a plurality of first bonding pads formed on the first active surface; a second chip having a second active surface and a corresponding second backside surface, and the second chip further having a plurality of second bonding pads formed on the second active surface, the second backside surface of the second chip adhered onto the first backside surface of the first chip, the second active surface of the second chip adhered onto the first surface of the substrate, the second bonding pads of the second chip exposed to the inside of the through hole of the substrate; a plurality of first wires, the first bonding pads electrically connected to the first mounting pads by the first wires; a plurality of second wires, the second bonding pads electrically connected to the second mounting pads by the second wires; and a molding compound covering the first chip, the second chip, the first wires and the second wires.

According to one preferred embodiment of the present invention, wherein when the first chip extends outside the second back surface of the second chip, the semiconductor package further has a plurality of supporters positioned between the first chip and the substrate to sustain the first chip. In addition, the first bonding pads of the first chip are formed on the edge region of the first active surface. The second bonding pads of the second chip are formed on the central region of the second active surface. The first mounting pads are formed on the first surface of the substrate and on the peripheral region of the area on which the second chip lays. The second mounting pads are formed on the second surface of the substrate and on the border region of the through hole.

Both the foregoing general description and the following detailed description are exemplary and explanatory only and are not restrictive of the invention, as claimed. It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1 is a schematic cross-sectional view showing a conventional semiconductor package.

FIG. 2 and FIG. 3 are schematic cross-sectional views respectively drawing conventional chip stack-type semiconductor packages.

FIG. 4 is a schematic cross-sectional view showing a chip stack-type semiconductor package according to a preferred embodiment of the present invention.

FIG. 5 and FIG. 6 respectively show schematic cross-sectional views of chip stack-type semiconductor packages according to other preferred embodiments of the present invention.

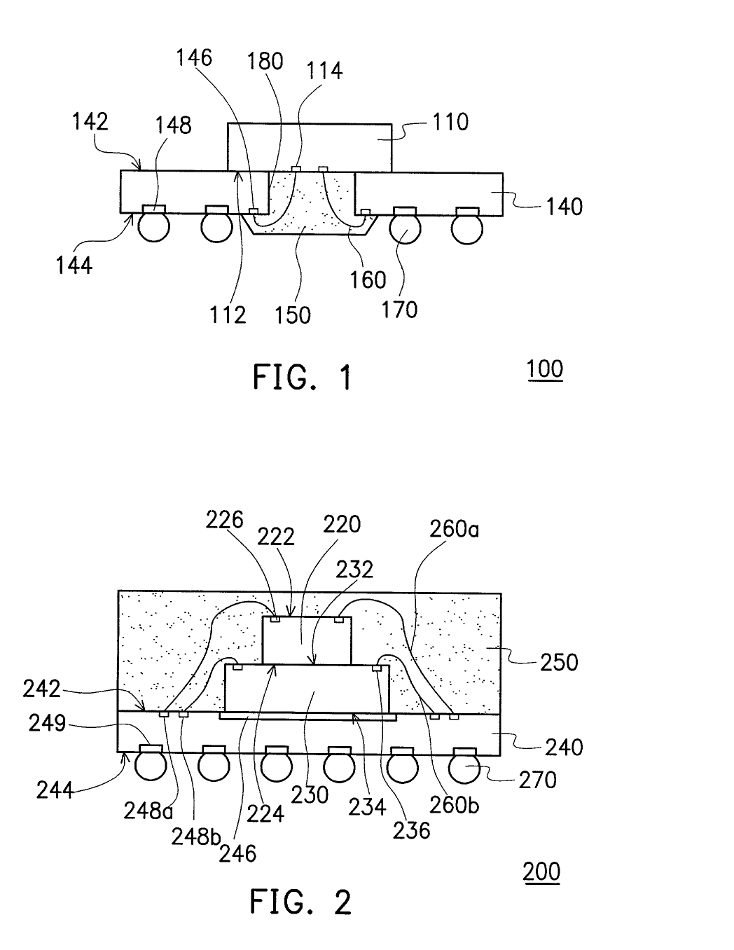

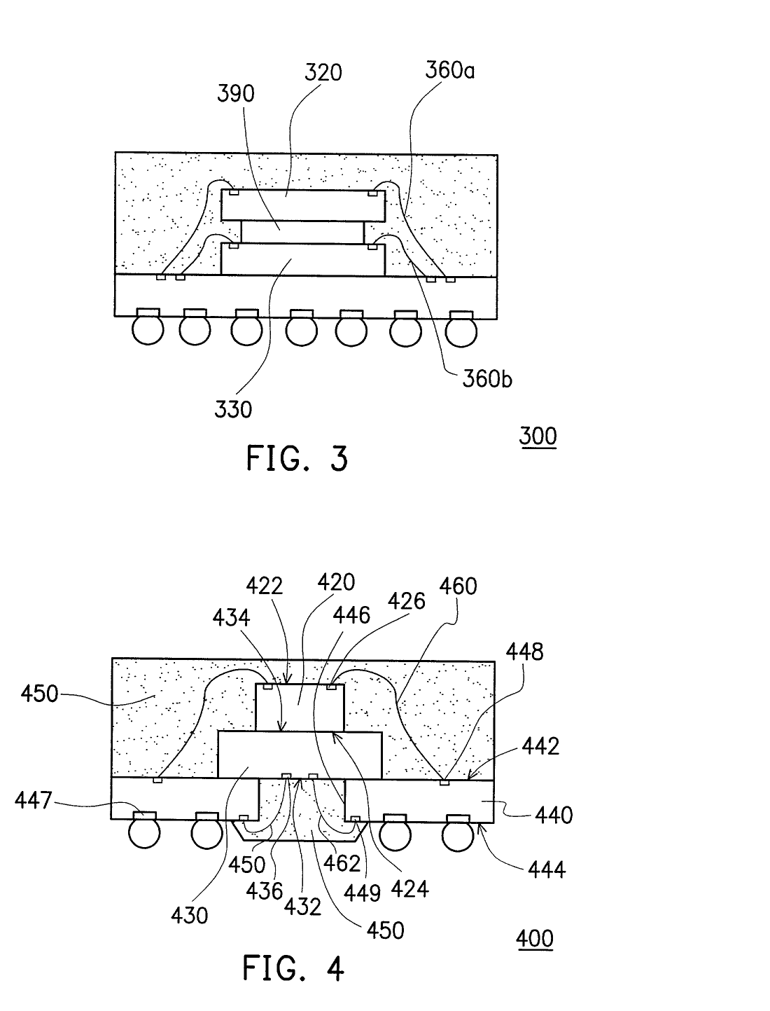

### DESCRIPTION OF THE PREFERRED EMBODIMENTS

FIG. 4 is a schematic cross-sectional view showing a chip stack-type semiconductor package according to a preferred embodiment of the present invention. A semiconductor package 400 is provided with a first chip 420, a second chip 430, a substrate 440, a plurality of first wires 460, a plurality of second wires 462, a plurality of solder balls 470 and a molding compound 450. The first chip 420 has a first active surface 422 and a corresponding first backside surface 424 and furthermore the first chip 420 has a plurality of first bonding pads 426 on the edge region of the first active surface 422. The second chip 430 has a second active surface 432 and a corresponding second backside surface 434 and the second chip 430 further has a plurality of second bonding pads 436 on the central region of the second active surface 432. The second backside surface 434 of the second chip 430 is adhered to the first backside surface 424 of the first chip 420, and the measure of the horizontal cross-sectional area of the first chip 420 is smaller than that of the second chip 430. Besides, the substrate 440 has a first surface 442 and a corresponding second surface 444, and further has a through hole 446 penetrating there through. The second active surface 432 of the second chip 430 is adhered to the first surface 442 of the substrate 440, and the second bonding pads 436 of the second chip 430 are exposed to the inside of the through hole 446 of the substrate 440. The substrate 440 further has a plurality of first mounting pads 448, a plurality of second mounting pads 449 and a plurality of ball pads 447. The first mounting pads 448 are formed on the first surface 442 of the substrate 440 and on the peripheral region of the area on which the second chip 430 lays. The second mounting pads 449 are formed on the second surface 444 of the substrate 440 and on the border region of the through hole 446. The ball pads 447 are formed on the second surface 444 of the substrate 440. In addition, the first bonding pads 426 are electrically connected to the first mounting pads 448 by the first wires 460; the second bonding pads 436 are electrically connected to the second mounting pads 449 by the second wires 462. The molding compound 450 covers the first chip 420, the second chip 430, the first wires 460 and the second wires 462. The solder balls 447 are attached on the ball pads 447 of the substrate 440.

In the above-mentioned semiconductor package 400, since the first wires 460 are extremely far away from the second wires 462, the first wires 460 and the second wires 462 can not touch each other and the cross talk between the first wires 460 and the second wires 462 can be prevented. Moreover, the first wires 460 can be directly bonded onto the substrate 440, not as the prior art states that they need specially cross other wires. Therefore, the length of the first wires 460 can be shortened, the opportunity of generating the delay and decay of a signal can be reduced, and the risk of collapsing wires can be dropped. In addition, the first mounting pads 448 and the second mounting pads 449 are respectively formed on both surfaces of the substrate 440, which thus the disposition of the circuits in a substrate can be improved and this kind of the substrate 440 can be easily designed and of relatively low cost. Besides, a plurality of chips are stacked in the semiconductor package 400 and thus it is benefited to integrate circuit systems. As far as a cost is concerned, the cost of the semiconductor package 400 packing a plurality of chips, according to the present invention, is lower than that of a plurality of semiconductor packages packing the chips respectively.

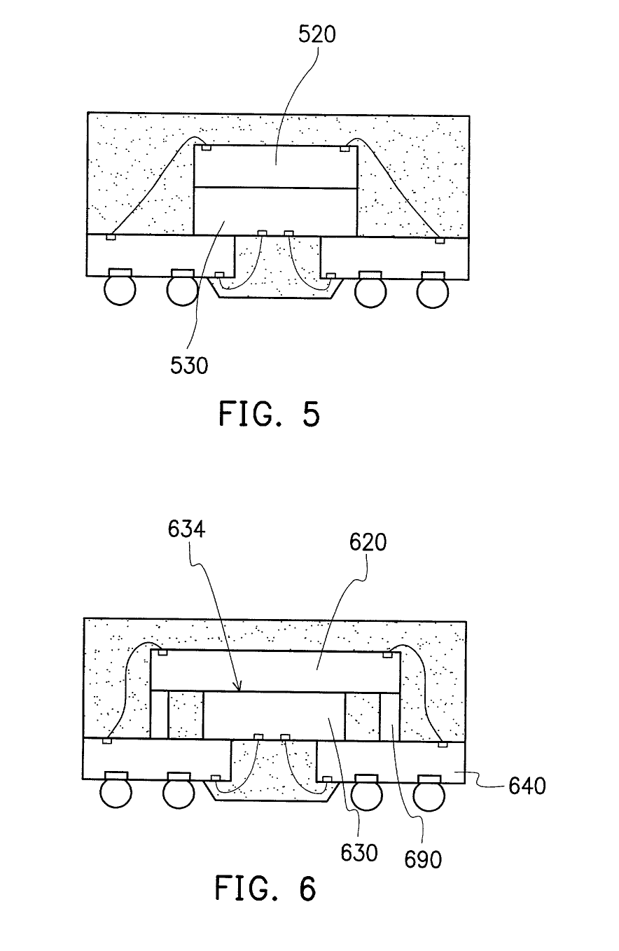

According to the above preferred embodiment, the measure of the horizontal cross-sectional area of the first chip is smaller than that of the second chip. However, the application of the present invention is not limited to the above description and the structure of stacked chips is also designed in another fashion, as shown in FIG. 5 and FIG. 6. FIG. 5 and FIG. 6 respectively show schematic cross-sectional views of chip stack-type semiconductor packages according to other preferred embodiments of the present invention. Referring to FIG. 5, a chip stack-type semiconductor package of the present invention can be applied to the condition that the measure of the horizontal cross-sectional area of the first chip 520 is the same as that of the second chip 530. Also, referring to FIG. 6, the first chip 620 extends outside the second back surface 634 of the second chip 630 and the semiconductor package 600 further has a plurality of supporter 690 positioned between the first chip 620 and the substrate 640 to sustain the first chip 620. The material of the supporter 600 is made of metal or polymer and it is preferred that the thermal expansion coefficient thereof is approximate to that of the second chip 630. Therefore, the chip stack-type semiconductor package of the present invention is not limited to the approximation of the dimensions of the chips. Compared with the prior art, a spacer between the first chip and the second chip need not be used, so that the thickness of the semiconductor package is kept extremely thin.

To sum up, the present invention has at least the following advantages:

1. Referring to the chip stack-type semiconductor package of the present invention, since the first wires are extremely far away from the second wires, the first wires and the second wires can not touch each other and the cross talk between the first wires and the second wires can be prevented.

2. Referring to the chip stack-type semiconductor package of the present invention, the first wires can be directly bonded onto the substrate, and they do not, as in the prior art, need to cross other wires. Therefore, the length of the first wires can be shortened, the opportunity of generating the delay and decay of a signal can be reduced, and the risk of collapsing wires can be dropped.

3. Referring to the chip stack-type semiconductor package of the present invention, the first mounting pads and the second mounting pads are respectively formed on both surfaces of the substrate, thus the disposition of the circuits in a substrate can be improved and this kind of the substrate can be easily designed and is of relatively low cost.

4. Referring to the chip stack-type semiconductor package of the present invention, a plurality of chips are stacked in the semiconductor package and thus it is beneficial to integrated circuit systems. As far as a cost is concerned, the cost of the semiconductor package packing a plurality of chips, according to the present invention, is lower than that of a plurality of semiconductor packages packing the chips respectively.

5. Referring to the chip stack-type semiconductor package of the present invention, it is not limited to the approximation of the dimensions of the chips and the thickness of the semiconductor package is kept extremely thin.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A chip stack-type semiconductor package comprising:
a first chip having a first active surface and a corresponding first backside surface and furthermore the first chip having a plurality of first bonding pads formed on the edge region of the first active surface;
a second chip having a second active surface and a corresponding second backside surface, and the second chip further having a plurality of second bonding pads formed on the central region of the second active surface, wherein the second backside surface of the second chip is adhered to the first backside surface of the first chip;
a substrate having a first surface and a corresponding second surface, the substrate further having a through hole penetrating there through, the second active surface of the second chip adhered onto the first surface of the substrate, the second bonding pads of the second chip exposed to the inside of the through hole of the substrate, the substrate further having a plurality of first mounting pads and a plurality of second mounting pads, the first mounting pads formed on the first surface of the substrate and on the peripheral region of the area on which the second chip lays, the second mounting pads formed on the second surface of the substrate and on the border region of the through hole;
a plurality of first wires, the first bonding pads electrically connected to the first mounting pads by the first wires;
a plurality of second wires, the second bonding pads electrically connected to the second mounting pads by the second wires; and
a molding compound covering the first chip, the second chip, the first wires and the second wires.

2. The chip stack-type semiconductor package according to claim 1, wherein when the first chip extends outside the second back surface of the second chip, the semiconductor package further has a plurality of supporters positioned between the first chip and the substrate to sustain the first chip.

3. The chip stack-type semiconductor package according to claim 2, wherein the thermal expansion coefficient of the supporter is approximate to that of the second chip.

4. A chip stack-type semiconductor package comprising:
a substrate having a first surface and a corresponding second surface, the substrate further having a through hole penetrating there through, the substrate further having a plurality of first mounting pads and a plurality of second mounting pads, the first mounting pads formed on the first surface of the substrate, the second mounting pads formed on the second surface of the substrate;
a first chip having a first active surface and a corresponding first backside surface and furthermore the first chip having a plurality of first bonding pads formed on the first active surface;
a second chip having a second active surface and a corresponding second backside surface, and the second chip further having a plurality of second bonding pads formed on the second active surface, the second backside surface of the second chip adhered onto the first backside surface of the first chip, the second active surface of the second chip adhered onto the first surface of the substrate, the second bonding pads of the second chip exposed to the inside of the through hole of the substrate;
a plurality of first wires, the first bonding pads electrically connected to the first mounting pads by the first wires;
a plurality of second wires, the second bonding pads electrically connected to the second mounting pads by the second wires; and
a molding compound covering the first chip, the second chip, the first wires and the second wires.

5. The chip stack-type semiconductor package according to claim 4, wherein when the first chip extends outside the second back surface of the second chip, the semiconductor package further has a plurality of supporters positioned between the first chip and the substrate to sustain the first chip.

6. The chip stack-type semiconductor package according to claim 5, wherein the thermal expansion coefficient of the supporter is approximate to that of the second chip.

7. The chip stack-type semiconductor package according to claim 4, wherein the first bonding pads of the first chip are formed on the edge region of the first active surface.

8. The chip stack-type semiconductor package according to claim 4, wherein the second bonding pads of the second chip are formed on the central region of the second active surface.

9. The chip stack-type semiconductor package according to claim 4, wherein the first mounting pads are formed on the first surface of the substrate and on the peripheral region of the area on which the second chip lays.

10. The chip stack-type semiconductor package according to claim 4, wherein the second mounting pads are formed on the second surface of the substrate and on the border region of the through hole.
